(19) United States
(12) Patent Application Publication
(10) Pub. No.: US 2024/0414960 A1
(43) Pub. Date: Dec. 12, 2024

(54) DISPLAY SUBSTRATE, DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yue TIAN, Beijing (CN); Xiangdan DONG, Beijing (CN); Cong FAN, Beijing (CN)

(21) Appl. No.: 18/705,605

(22) PCT Filed: Apr. 20, 2023
(86) PCT No.: PCT/CN2023/089588

§ 371 Date: Apr. 29, 2024

(30) Foreign Application Priority Data
Apr. 26, 2022 (CN) 202210447766.9

(51) Int. Cl. H10K 59/126; H10K 59/131

(52) U.S. Cl. CPC H10K 59/126; H10K 59/131

(57) ABSTRACT

A display substrate, a display panel and a display apparatus. The display substrate comprises: a substrate (100); a shielding layer (200), the shielding layer (200) being arranged on one side of the substrate and comprising a plurality of shielding parts (210) arranged at intervals, a plurality of first connecting lines (220) and an edge line (230), the plurality of shielding parts being connected by the first connecting lines, and the edge line being arranged on the peripheries of the plurality of shielding parts and being connected to end parts of the first connecting lines; and a driving thin film transistor, said transistor comprising an active layer arranged on the side of the shielding layer away from the substrate, and the orthographic projection of each shielding part on the substrate covering at least part of the orthographic projection of the active layer on the substrate.

### CROSS-REFERENCE TO RELATED APPLICATION

The present application is a U.S. National Phase Entry of International Application No. PCT/CN2023/089588 having an international filing date of Apr. 20, 2023, which claims priority to Chinese Patent Application No. 202210447766.9, filed to the CNIPA on Apr. 26, 2022 and entitled “Display Substrate, Display Panel and Display Apparatus”. Contents of the above-identified applications should be regarded as being incorporated herein by reference.

### TECHNICAL FIELD

Embodiments of the present disclosure relate to, but are not limited to, the field of display technologies, and particularly, to a display substrate, a display panel and a display apparatus.

### BACKGROUND

With the rapid development and application of OLED display technology, such as AMOLED (Active-matrix organic light emitting diode), users put forward more diversified demands for OLED products, and OLED products with lower power consumption and higher image quality have attracted the attention of many users. At present, in order to reduce the power consumption of the display panel and improve the image quality of the display panel, a shielding layer may be provided under the driving thin film transistor. However, in the process of ELA (Excimer Laser Annealing, which means that amorphous silicon film is irradiated by excimer laser to realize the transformation from amorphous silicon film to polysilicon film), the weak position of the shielding layer has relatively poor ability to resist ESD (Electro-Static discharge), which is easy to peel off during the process of ELA, resulting in a decrease in product yield.

Therefore, the current display substrate, display panel and display apparatus still need to be improved.

### SUMMARY

The following is a summary of subject matter described in the present disclosure in detail. This summary is not intended to limit the protection scope of claims.

An exemplary embodiment of the present disclosure provides a display substrate, including:
a base substrate;
a shielding layer, wherein the shielding layer is provided on a side of the base substrate and includes a plurality of shielding parts provided at intervals, a plurality of first connecting lines, and an edge line; the plurality of shielding parts are connected by the first connecting lines; and the edge line is provided on peripheries of the plurality of shielding parts and connected to end parts of the first connecting lines; and
a driving thin film transistor, wherein the driving thin film transistor includes an active layer provided on a side of the shielding layer away from the base substrate; and an orthographic projection of each shielding part on the base substrate covers at least a partial area of an orthographic projection of the active layer on the base substrate.

In an exemplary embodiment, a plurality of driving thin film transistors are provided, and each of the plurality of driving thin film transistors includes an active layer.

The orthographic projection of each shielding part on the base substrate respectively covers at least a partial area of the orthographic projection of the active layer on the base substrate.

In an exemplary embodiment, a width of the edge line is 3 to 5 times a width of the first connecting lines.

In an exemplary embodiment, the width of the edge line is 18 to 22 microns.

In an exemplary embodiment, the plurality of shielding parts are arranged in an array in a first direction and a second direction, and the first connecting lines further include:
a plurality of first connecting segments extending in the first direction and extending to the edge line and connecting the shielding parts arranged in the first direction; and
a plurality of second connecting segments extending in the second direction and extending to the edge line and connecting the shielding parts arranged in the second direction.

The first direction intersects with the second direction.

In an exemplary embodiment, the shielding layer further includes a second connecting line. An end part of the second connecting line is not connected to the edge line, and the second connecting line includes a third connecting segment extending in the first direction and a fourth connecting segment extending in the second direction.

The third connecting segment is located between a first connecting segment and the edge line, and connects the shielding parts arranged in the first direction. The fourth connecting segment is located between a second connecting segment and the edge line, and connects the shielding parts arranged in the second direction.

In an exemplary embodiment, the third connecting segment and the fourth connecting segment are straight lines or are curved in partial areas.

In an exemplary embodiment, the shielding layer further includes a raised structure provided at a position where part of the first connecting lines intersects with the edge line.

In an exemplary embodiment, the edge line is a smooth curve.

In an exemplary embodiment, an included angle between the edge line and the first connecting lines at an intersection is less than or equal to 90 degrees.

In an exemplary embodiment, the driving thin film transistor further includes a source and a drain, both of which are electrically connected to the active layer by through holes. An orthographic projection of the through holes on the base substrate and an orthographic projection of the edge line on the base substrate have no overlapping region.

In an exemplary embodiment, a minimum distance between the edge line and the through holes is greater than or equal to 2.5 microns.

An exemplary embodiment of the present disclosure further provides a display panel, including the display substrate according to any of the embodiments described above.

An exemplary embodiment of the present disclosure further provides a display apparatus, including the display substrate according to any of the embodiments described above.

Other aspects of the present disclosure may be comprehended after the drawings and the detailed descriptions are read and understood.

### BRIEF DESCRIPTION OF DRAWINGS

FIG. 1 shows a schematic diagram of a structure of a shielding layer according to an embodiment of the present disclosure;

FIG. 2 shows a schematic diagram of a partial structure of a display substrate according to an embodiment of the present disclosure;

FIG. 3 shows a schematic diagram of a partial structure of a shielding layer according to an embodiment of the present disclosure;

FIG. 4 shows a schematic diagram of a partial structure of a shielding layer according to another embodiment of the present disclosure;

FIG. 5 shows a schematic diagram of a partial structure of a display substrate according to another embodiment of the present disclosure;

FIG. 6 shows a schematic diagram of a partial structure of a display substrate according to still another embodiment of the present disclosure;

FIG. 7 shows a schematic diagram of a partial structure of a shielding layer according to still another embodiment of the present disclosure;

FIG. 8 shows a schematic diagram of a partial structure of a comparative shielding layer;

FIG. 9 shows a schematic diagram of a partial structure of a display substrate according to yet another embodiment of the present disclosure;

FIG. 10 shows a schematic diagram of a partial structure of a display substrate according to yet another embodiment of the present disclosure; and

FIG. 11 shows a schematic diagram of a partial structure of a display substrate according to yet another embodiment of the present disclosure.

### DETAILED DESCRIPTION

Embodiments of the present disclosure are described in detail below. Embodiments described below are exemplary and are only used for explaining the present disclosure, but should not be construed as limitations on the present disclosure. The embodiments in which technologies or conditions are not indicated shall be carried out according to technologies or conditions described in literatures in the art or according to a product specification.

The embodiments and features in the embodiments of the present disclosure may be randomly combined with each other if there is no conflict.

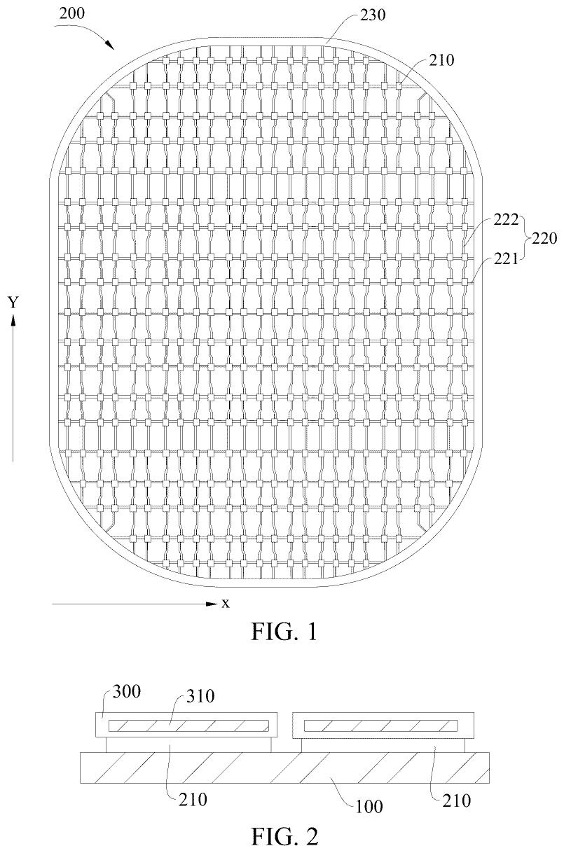

In one aspect of the present disclosure, the present disclosure provides a display substrate. Referring to FIGS. 1 and 2, the display substrate includes a base substrate 100, a shielding layer 200 and a driving thin film transistor 300. The shielding layer 200 is provided on a side of the base substrate 100 and includes a plurality of shielding parts 210 provided at intervals, a plurality of first connecting lines 220 and an edge line 230. The plurality of shielding parts 210 are connected by the first connecting lines 220. The edge line 230 is provided on peripheries of the plurality of shielding parts 210 and connected to end parts of the first connecting lines 220. The driving thin film transistor 300 includes an active layer 310 provided on a side of the shielding layer 200 away from the base substrate 100. An orthographic projection of each shielding part 210 on the base substrate 100 covers at least a partial area of an orthographic projection of the active layer 310 on the base substrate 100. Therefore, the shielding layer integrates the first connecting lines, the shielding parts and other structures through the edge line, so that the shielding layer has better performance of resisting electrostatic discharge as a whole, and may avoid static electricity accumulation caused by electrostatic discharge in an excimer laser annealing process, thereby avoiding the peeling problem of the shielding layer. In addition, when the display substrate is used for the display panel, the provision of the shielding layer may also reduce power consumption, and make the display panel have good image quality, which is beneficial to improving the experience effect of users.

In an exemplary embodiment, the shielding layer 200 is a whole-layer structure provided on a side of the base substrate 100. However, in order to more clearly explain the technical scheme of the present disclosure, only the shielding parts 210 in the shielding layer 200 are shown in FIG. 2, and although the edge line 230, the first connecting lines 220 and other structures of the shielding layer 200 are all provided on the same layer as the shielding parts 210, they are not shown in FIG. 2. FIG. 2 shows only the case where two driving thin film transistors 300 are included in the display substrate, but it should be understood by those skilled in the art that the display substrate may include a plurality of driving thin film transistors 300, each of which may include one active layer 310. In some embodiments of the present disclosure, an orthographic projection of each shielding part 210 on the base substrate 100 may respectively cover at least a partial area of an orthographic projection of one active layer 310 on the base substrate 100 (FIG. 2 takes the orthographic projection of each shielding part 210 on the base substrate 100 completely covering the orthographic projection of one active layer 310 on the base substrate 100 respectively as an example).

According to an embodiment of the present disclosure, the shielding layer 200 may be made of a metal material. For example, the shielding layer 200 may be made of a metal material such as copper, aluminum, titanium, so that defects caused by laser irradiation on the base substrate 100 may be avoided during the excimer laser annealing process. Moreover, the shielding layer made of a metal material may better reduce power consumption.

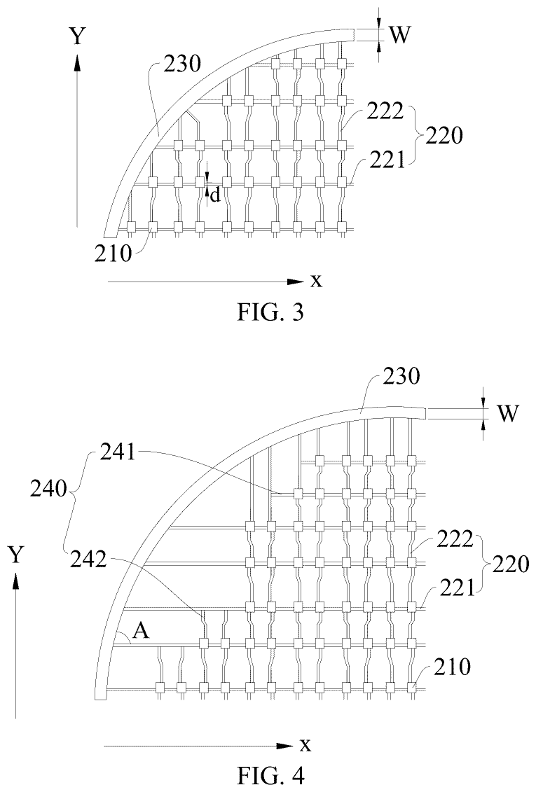

According to some embodiments of the present disclosure, referring to FIGS. 1 and 3 (FIG. 3 shows only a partial structure of the shielding layer 200), the plurality of shielding parts 210 are arranged in an array in a first direction (X direction shown in FIGS. 1 and 3) and a second direction (Y direction shown in FIGS. 1 and 3). The first connecting lines 220 further include a plurality of first connecting segments 221 and a plurality of second connecting segments 222. The first connecting segments 221 extend in the first direction (X direction) and extend to the edge line 230, and connect the shielding parts 210 arranged in the first direction (X direction). The second connecting segments 222 extend in the second direction (Y direction) and extend to the edge line 230, and connect the shielding parts 210 arranged in the second direction (Y direction). The first direction (X direction) intersects with the second direction (Y direction). Taking the X direction as a row direction and the Y direction as a column direction as an example, the first connecting lines 210 include a plurality of first connecting segments 221 extending in the first direction (X direction) and a plurality of second connecting segments 222 extending in the second direction (Y direction). The shielding parts 210 of each row are connected by one first connecting segment 221, that is, each of the plurality of first connecting segments 221 connects a row of shielding parts 210. The shielding parts 210 of each column are connected by one second connecting segment 222, that is, each of the plurality of second connecting segments 222 connects a column of shielding parts 210. Therefore, it is beneficial to further improve the integration effect of the shielding layer, and then it is beneficial to avoiding the peeling phenomenon of the shielding layer during excimer laser annealing process.

In an exemplary embodiment, the first connecting segments 221 extend in the first direction (X direction) and the second connecting segments 222 extend in the second direction (Y direction), which means that an overall extending direction of the first connecting segments 221 is the X direction and an overall extending direction of the second connecting segments 222 is the Y direction. However, the first connecting segments 221 and the second connecting segments 222 may be either straight lines or curved lines. That is, in a manufacturing process, in order to make an overall structure of the display substrate have better stability, the first connecting segments 221 and the second connecting segments 222 may be curved in partial areas as long as it is ensured that the first connecting segments 221 overall extend in the X direction and connect a row of shielding parts 210 arranged in the X direction and the second connecting segments 222 overall extend in the Y direction and connect a row of shielding parts 210 arranged in the Y direction.

As can be seen from FIGS. 1 and 3, one of the shielding parts 210 may be in contact with both the first connecting segment 221 and the second connecting segment 222. In the first direction (X direction), two adjacent shielding parts 210 may be connected by a portion of the first connecting segment 221, and in the second direction (Y direction), two adjacent shielding parts 210 may be connected by a portion of the second connecting segment 222. The first direction (X direction) intersects with the second direction (Y direction), which may be understood as that the first direction (X direction) and the second direction (Y direction) are not parallel in a plane where the shielding layer 200 is located. According to some exemplary embodiments of the present disclosure, an included angle between the first direction (X direction) and the second direction (Y direction) may be 90 degrees, thereby facilitating wiring and fabrication of the shielding layer.

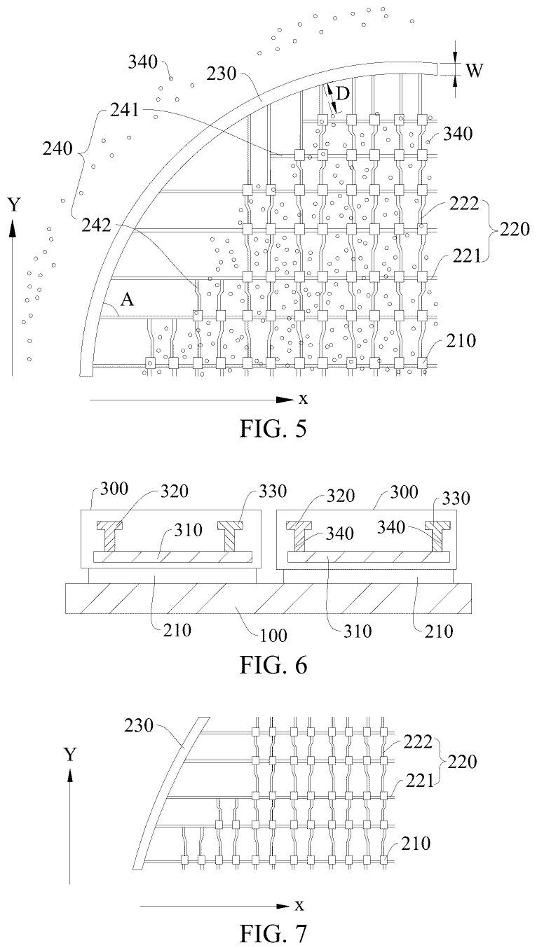

According to other embodiments of the present disclosure, referring to FIGS. 4 and 5, the shielding layer 200 may further include a second connecting line 240. An end part of the second connecting line 240 is not connected to the edge line 230, and the second connecting line 240 may include a third connecting segment 241 extending in the first direction (X direction) and a fourth connecting segment 242 extending in the second direction (Y direction). The third connecting segment 241 is located between the first connecting segment 221 and the edge line 230, and connects the shielding parts 210 arranged in the first direction (X direction). The fourth connecting segment 242 is located between the second connecting segment 222 and the edge line 230 and connects the shielding parts 210 arranged in the second direction (Y direction).

In an exemplary embodiment, the end part of the second connecting line 240 is not connected to the edge line 230, which means that the end part of the second connecting line 240 does not extend to the edge line 230. At a bending position (turning position) of the shielding layer 200, the edge line 200 has a certain radian, and a wiring space is relatively small. In order to facilitate wiring, the number of the shielding parts 210 at the bending position of an edge of the shielding layer 200 may be correspondingly reduced on the basis of ensuring the image quality of the display picture. At a position close to the edge of the shielding layer 200, the shielding parts 210 may be connected by the second connecting line 240, and the end part of the second connecting line 240 only needs to extend to a certain first connecting line 220 close to the bending position, but does not need to extend to the edge line 230, which may also achieve good integration effects and facilitate the overall wiring of the shielding layer. FIGS. 4 and 5 only show a structure of a bending position of the shielding layer 200. When the shielding layer 200 is provided as the structure shown in FIG. 1, each of four bending positions of the shielding layer 200 may have a structure similar to that shown in FIGS. 4 and 5. Alternatively, the second connecting line 240 may include one or more third connecting segments 241 extending in the first direction (X direction), or may include one or more fourth connecting segments 242 extending in the second direction (Y direction). Taking the X direction as a row direction and the Y direction as a column direction as an example, one third connecting segment 241 is used for connecting a row of shielding parts 210, and one fourth connecting segment 242 is used for connecting a column of shielding parts 210. When a plurality of (two or more) third connecting segments 241 and/or a plurality of (two or more) fourth connecting segments 242 are provided, each of the plurality of third connecting segments 241 connects a row of shielding parts 210, and each of the plurality of fourth connecting segments 242 connects a column of shielding parts 210.

In an exemplary embodiment, the third connecting segment 241 and the fourth connecting segment 242 may be straight lines or may be curved in partial areas, as long as it is ensured that the third connecting segment 241 overall extends in the X direction and connects the shielding parts 210 arranged in the X direction, and the fourth connecting segment 242 overall extends in the Y direction and connects the shielding parts 210 arranged in the Y direction.

According to an embodiment of the present disclosure, referring to FIG. 3, a width W of the edge line 230 is 3 to 5 times a width d of the first connecting line 220. For example, the width W of the edge line 230 may be 3 times, 3.5 times, 4 times, 4.5 times, 5 times and the like the width d of the first connecting line 220, so that the edge line is wider, which may well integrate the first connecting lines, the shielding parts and other structures and further improve performance of the shielding layer against electrostatic discharge.

According to an embodiment of the present disclosure, referring to FIGS. 3 to 5, the width W of the edge line 230 may be 18 to 22 microns, for example, 18 microns, 18.5 microns, 19 microns, 19.3 microns, 19.5 microns, 19.7 microns, 20 microns, 20.2 microns, 20.5 microns, 20.8 microns, 21 microns, 21.5 microns, 22 microns and the like, so that the width W of the edge line is larger, which may further improve performance of the shielding layer against electrostatic discharge. Moreover, by providing the width of the edge line within the above range, the arrangement requirements of the first connecting lines, the shielding parts (and the second connecting line) and other structures in the shielding layer may be better met.

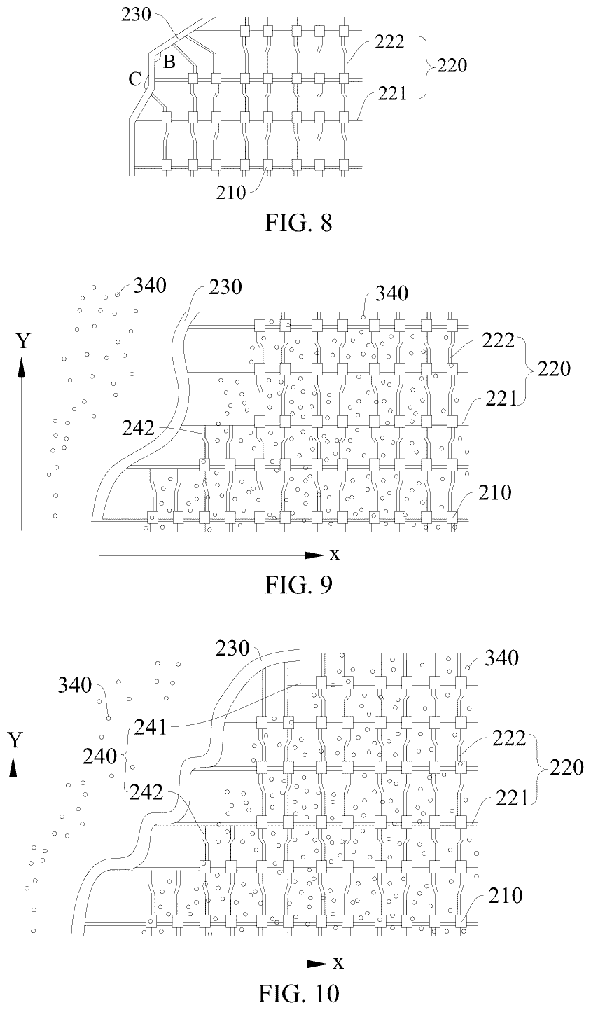

According to an embodiment of the present disclosure, referring to FIGS. 1, 3-5, 7 and 9-11, the edge line 230 does not have a bending angle. In the present disclosure, the bending angle refers to a sharp included angle (referring to included angles B and C in FIG. 8). When the edge line has a bending angle, there will be a sharp area on an edge of the shielding layer. In the excimer laser annealing process, the sharp area is easy to generate static electricity accumulation, which will lead to the peeling problem on the edge of the shielding layer. In the present disclosure, if there is no bending angle on the edge line, there will be no sharp area on the edge of the shielding layer, thus avoiding the possible adverse effects caused by the sharp area.

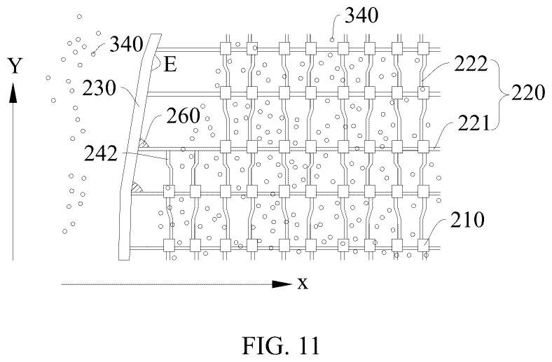

According to some embodiments of the present disclosure, referring to FIGS. 1, 3-5, 7 and 9-11, the edge line 230 may be a smooth curve, that is, the curve does not have a bending angle (included angles B and C, where the bending angle refers to an included angle less than 160 degrees) as shown in FIG. 8, so that the peeling problem of the shielding layer may be better avoided, thereby further improving the overall performance of the display substrate. In some embodiments of the present disclosure, the smooth curve may be in a bending position of the shielding layer as shown in FIGS. 1, 3-5, 7, 9 and 10, or may be in a non-bending position of the shielding layer. The edge line 230 in the present disclosure may be provided in a plurality of different shapes as long as there is no sharp bending angle in the edge line. According to some exemplary embodiments of the present disclosure, referring to FIGS. 3-5 and 7, the edge line at one bending position of the shielding layer may be formed by only a segment of an arc. According to other exemplary embodiments of the present disclosure, referring to FIGS. 9 and 10, the edge line at one bending position of the shielding layer may be formed by connecting a plurality of arcs, two adjacent arcs are smoothly connected, and there is no bending angle shown in FIG. 8. Referring to FIG. 10, the edge line at one bending position of the shielding layer may be in a stepped shape. According to yet other exemplary embodiments of the present disclosure, referring to FIG. 11, the edge line at one bending position of the shielding layer may be formed by connecting a plurality of straight line segments, two adjacent straight line segments are smoothly connected, and there is no bending angle shown in FIG. 8. FIG. 11 shows an included angle E (an included angle less than 180 degrees) between two adjacent straight line segments, and the included angle E is greater than 160 degrees, which may realize smooth connection between the straight line segments, thereby effectively avoiding static electricity accumulation. According to yet other exemplary embodiments of the present disclosure, the edge line at one bent position of the shielding layer may be formed by connecting a plurality of straight line segments and/or a plurality of arcs, as long as the edge line does not have a bending angle, for example, two straight line segments may be smoothly connected by an arc. Of course, it should be understood by those skilled in the art that the edge line may either in the curved shape of FIG. 5, 9, 10, or 11, or may be in other smooth curved shapes at other bending positions of the shielding layer.

According to some embodiments of the present disclosure, referring to FIG. 11, the shielding layer 200 may further include a raised structure 260 that may be provided at a position where at least a portion of the first connecting lines 220 intersects with the edge line, so that the provision of the raised structure may be more conducive to discharging static electricity near a position where the edge line intersects with the first connecting lines, thereby further avoiding an electrostatic peeling phenomenon caused by static electricity accumulation. It will be understood by those skilled in the art that the raised structure 260, the first connecting lines 220, the shielding parts 210, the edge line 230 and other structures are of an integrated structure, and may be manufactured by a same manufacturing process and a same step.

According to some exemplary embodiments of the present disclosure, referring to FIGS. 4 and 5, the edge line 230 does not have a bending angle, and an included angle A between the edge line 230 and the first connecting line 220 at an intersection is less than or equal to 90 degrees, which may further improve the overall performance of the display substrate, and facilitate a reasonable layout of the first connecting lines and the edge line.

According to other exemplary embodiments of the present disclosure, referring to FIGS. 5, 6, 9 and 10, the driving thin film transistor 300 further includes a source 320 and a drain 330, both of which are electrically connected to the active layer 310 by through holes 340. An orthographic projection of the through holes 340 on the base substrate 100 and an orthographic projection of the edge line 230 on the base substrate 100 have no overlapping region, that is, provision of the through holes 340 is avoided at the edge line 230, so that adverse effects on the edge line caused by the step of forming the through holes in the process of manufacturing the display substrate can be avoided, thereby avoiding the formation of weak regions difficult to resist electrostatic discharge on the edge line and also avoiding static electricity generation. As can be seen from FIGS. 5, 9 and 10, the through holes 340 may also be provided in a peripheral region of the edge line 230 (a side of the edge line 230 away from the shielding parts 210). It should be noted that the edge line 230 also needs to avoid the through holes 340 provided in the peripheral region thereof.

According to some embodiments of the present disclosure, referring to FIG. 5, a minimum distance D between the edge line 230 and the through holes 340 is greater than or equal to 2.5 microns. Therefore, there is a certain distance between the edge line and the through holes, which may better avoid the impact of punching on the edge line, thereby making the edge line have good performance of resisting electrostatic discharge, and improving the overall stability of the display substrate. In some exemplary embodiments of the present disclosure, the minimum distance D between the edge line 230 and the through holes 340 may be 2.5 microns. FIG. 5 also shows a partial structure of the shielding layer 200 and a portion of the through holes 340 in the thin film transistor 300, which is only for the purpose of explaining the technical scheme of the present disclosure. There is certain spacing between the through holes 340 and the edge line 230, but it should be understood by those skilled in the art that the through holes 340 and the shielding layer 200 are not provided in a same layer.

Generally speaking, by providing the edge line to integrate the first connecting lines, the shielding parts and other structures of the shielding layer, the present disclosure may improve the performance of the shielding layer against electrostatic discharge, and maintain the stability of the shielding layer during the excimer laser annealing process. When the display substrate is applied to a display panel, provision of the shielding layer may make the display panel have good image quality and may reduce power consumption. Furthermore, a wider edge line may be provided to further improve the performance of the shielding layer against electrostatic discharge. In addition, the edge line may further be configured to have no bending angle, thereby avoiding the adverse effects that may be caused by sharp areas in the edge line.

In another aspect of the present disclosure, the present disclosure provides a display panel including the display substrate described above. Therefore, the display panel has all features and advantages of the display substrate described above, which will not be repeated here. Generally speaking, the display panel has good display performance, good image quality and low power consumption. In an exemplary embodiment, the shielding layer 200 is provided in a display area of the display panel, and the edge line 230 is provided at a periphery of the display area.

According to an embodiment of the present disclosure, the display panel may be a display panel of a LTPO (Low Temperature Polycrystalline Oxide, i.e., replacing low temperature polysilicon in part of the circuit with an oxide to improve leakage current) product.

In yet another aspect of the present disclosure, the present disclosure proposes a display apparatus including the display substrate described above. Therefore, the display apparatus has all features and advantages of the display substrate described above, which will not be repeated here. Generally speaking, the display apparatus has good image quality and low power consumption, which is beneficial to improving the experience effect of users.

According to the embodiments of the present disclosure, there is no special requirement for the type of the display apparatus, and those skilled in the art may flexibly select the display apparatus according to actual demand. For example, the display apparatus may be a mobile phone, an iPad, a notebook and the like.

As can be understood by those skilled in the art, the display apparatus has necessary structures and components of a conventional display apparatus besides the display substrate described above. Taking a mobile phone as an example, besides the display substrate described above, it further includes necessary structures and components such as a battery back cover, a middle frame, a touch panel, an audio module, a motherboard and the like.

In the present disclosure, the terms “first”, “second”, “third” and “fourth” are used for descriptive purposes only and cannot be interpreted as indicating or implying relative importance or implicitly indicating the number of technical features indicated. Thus, features defined by “first”, “second”, “third” or “fourth” may explicitly or implicitly include one or more of such features. In the description of the present disclosure, a meaning of “a plurality of” is two or more than two, unless defined otherwise explicitly.

In the description of the specification, the description with reference to the terms “an embodiment”, “another embodiment”, “some embodiments”, “some exemplary embodiments”, or “an exemplary embodiment” or the like means that the features, structures, materials, or characteristics described in conjunction with the embodiment or example are included in at least one embodiment or example of the present disclosure. In this specification, a schematic expression of the above terms does not necessarily refer to a same embodiment or example. Moreover, described features, structures, materials, or characteristics may be combined in any one or more embodiments or examples in a suitable manner. In addition, if there is no conflict, those skilled in the art may integrate and combine different embodiments or examples and features of different embodiments or examples described in this specification.

Although the embodiments of the present disclosure have been shown and described above, it may be understood that the above embodiments are exemplary and cannot be interpreted as limitations on the present disclosure. An ordinary person skilled in the art may make changes, modifications, substitutions, and variations to the above embodiments within the scope of the present disclosure.

1. A display substrate, comprising:
a base substrate;
a shielding layer, wherein the shielding layer is provided on a side of the base substrate and comprises a plurality of shielding parts provided at intervals, a plurality of first connecting lines, and an edge line; the plurality of shielding parts are connected by the first connecting lines; and the edge line is provided on peripheries of the plurality of shielding parts and connected to end parts of the first connecting lines; and
a driving thin film transistor, wherein the driving thin film transistor comprises an active layer provided on a side of the shielding layer away from the base substrate; and an orthographic projection of each shielding part on the base substrate covers at least a partial area of an orthographic projection of the active layer on the base substrate.

2. The display substrate according to claim 1, wherein a plurality of driving thin film transistors are provided, and each of the plurality of driving thin film transistors comprises an active layer; and
the orthographic projection of each shielding part on the base substrate respectively covers at least a partial area of the orthographic projection of the active layer on the base substrate.

3. The display substrate according to claim 1, wherein a width of the edge line is 3 to 5 times a width of the first connecting lines.

4. The display substrate according to claim 3, wherein the width of the edge line is 18 to 22 microns.

5. The display substrate according to claim 1, wherein the plurality of shielding parts are arranged in an array in a first direction and a second direction, and the first connecting lines further comprise:
a plurality of first connecting segments extending in the first direction and extending to the edge line and connecting the shielding parts arranged in the first direction; and
a plurality of second connecting segments extending in the second direction and extending to the edge line and connecting the shielding parts arranged in the second direction;
wherein the first direction intersects with the second direction.

6. The display substrate according to claim 5, wherein the shielding layer further comprises a second connecting line, an end part of the second connecting line is not connected to the edge line, and the second connecting line comprises a third connecting segment extending in the first direction and a fourth connecting segment extending in the second direction; and
wherein the third connecting segment is located between a first connecting segment and the edge line, and connects the shielding parts arranged in the first direction; and the fourth connecting segment is located between a second connecting segment and the edge line, and connects the shielding parts arranged in the second direction.

7. The display substrate according to claim 6, wherein the third connecting segment and the fourth connecting segment are straight lines or are curved in partial areas.

8. The display substrate according to claim 7, wherein the shielding layer further comprises a raised structure provided at a position where part of the first connecting lines intersects with the edge line.

9. The display substrate according to claim 1, wherein the edge line is a smooth curve.

10. The display substrate according to claim 1, wherein an included angle between the edge line and the first connecting lines at an intersection is less than or equal to 90 degrees.

11. The display substrate according to claim 1, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.

12. The display substrate according to claim 11, wherein a minimum distance between the edge line and the through holes is greater than or equal to 2.5 microns.

13. A display panel, comprising the display substrate according to claim 1.

14. A display apparatus, comprising the display substrate according to claim 1.

15. The display substrate according to claim 2, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.

16. The display substrate according to claim 3, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.

17. The display substrate according to claim 4, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.

18. The display substrate according to claim 5, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.

19. The display substrate according to claim 6, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.

20. The display substrate according to claim 7, wherein the driving thin film transistor further comprises a source and a drain, both of the source and the drain are electrically connected to the active layer by through holes; and an orthographic projection of the through holes on the base substrate and an orthographic projection of the edge line on the base substrate have no overlapping region.
